(19) United States
(12) Patent Application Publication
(10) Pub. No.: US 2017/0301481 A1
(43) Pub. Date: Oct. 19, 2017

(54) QUANTUM DOTS-SENSITIZED SOLAR CELL AND METHOD OF ENHANCING THE OPTOELECTRONIC PERFORMANCE OF A QUANTUM DOTS-SENSITIZED SOLAR CELL USING A CO-ADSORBENT

(71) Applicant: National Taiwan University of Science and Technology, Taipei City (TW)

(72) Inventors: Jia-Yaw CHANG, Taipei City (TW); Chen-Hei LI, Taipei City (TW); Ya-Han CHIANG, Taipei City (TW)

(73) Assignee: National Taiwan University of Science and Technology, Taipei City (TW)

(21) Appl. No.: 15/432,787

(22) Filed: Feb. 14, 2017

(30) Foreign Application Priority Data
Apr. 15, 2016 (TW) 105111797

(51) Int. Cl. H01G 9/20; H01G 9/00; H01L 51/00

(52) U.S. Cl. CPC H01G 9/2054; H01G 9/204; H01G 9/2004; H01G 9/2027; H01G 9/2059; H01G 9/0029; H01G 9/2031; H01L 51/004; H01L 51/005; H01L 51/0093

(57) ABSTRACT

The invention provides a quantum dots-sensitized solar cell and a method of enhancing the optoelectronic performance of a quantum dots-sensitized solar cell using a co-adsorbent, in which a bifunctional molecule is used as the co-adsorbent and is mixed with aqueous quantum dots to form a quantum dots sensitizer, thereby improving the photoelectric conversion efficiency of the solar cell.

### FIELD OF THE INVENTION

The present invention relates to a quantum dots-sensitized solar cell (QDSSC) and a method of enhancing the optoelectronic performance of a quantum dots-sensitized solar cell using a co-adsorbent, in which a bifunctional molecule is used as the co-adsorbent and is mixed with aqueous quantum dots to form a quantum dots sensitizer, thereby improving the photoelectric conversion efficiency of the solar cell.

### BACKGROUND TO THE INVENTION

As an alternative energy, solar energy has features such as wide distribution and ease to obtain, and its utilization is by a conversion of light energy into electric energy through a solar cell, during which conversion no environmental pollution is caused; therefore, solar energy is a must potential renewable energy to be developed.

The solar cell can be classified into three types including, in development sequence, silicon solar cells, film solar cells, and dye-sensitized solar cells (DSSCs). Among them, the DSSC as the third generation is operated by capturing incident light through sensitive dyes and converting the energy of photons into electric energy. The DSSC can be made of a variety of materials, and its manufacturing process needs no clean room and thus is simpler than those of other solar cells; therefore, the DSSC has an advantage of reducing manufacturing cost. However, most of highly efficient DSSCs use organic ruthenium complexes as the dye, which is expensive in production cost and cannot be decomposed in the environment. Therefore, in recent years, industries and research units were enthusiastically looking for alternative sensitizers such as, for example, quantum dots, to replace the organic ruthenium complexes.

On the other hand, the photoelectric conversion efficiency of a solar cell depends on light capture efficiency, electron injection efficiency, electron collection efficiency, etc., of which the electron injection efficiency can be enhanced by using a co-adsorbent to prevent the dye from gathering on the surface of the semiconductor, so as to improve the photoelectric conversion efficiency. For example, CN 103295795 B discloses using organic materials of acetylacetone and its derivatives as the co-adsorbent, which improve the photoelectric conversion efficiency of the DSSC to a certain extent.

### SUMMARY OF THE INVENTION

In view that the production cost of the conventional technology in which organic ruthenium complexes are used as the sensitizer is expensive and the optoelectronic performance of the DSSCs using inorganic materials as the sensitizer is too low, the present invention therefore provides a quantum dots-sensitized solar cell, in which quantum dots are used as the sensitizer and a co-adsorbent is used to improve the optoelectronic performance of the solar cell.

According to one aspect of the present invention, provided is a quantum dots-sensitized solar cell, comprising:
a photoelectrode, formed on a first substrate and having a quantum dots sensitizer adsorbed thereon;
a back electrode, formed on a second substrate; and
a polysulfide electrolyte, injected between the photoelectrode and the back electrode;
wherein the photoelectrode having the quantum dots sensitizer adsorbed is modified by a co-adsorbent, and the co-adsorbent has a structure of HS—R—COOH or HS—R—OH where R represents a substituted or unsubstituted organic carbon chain having 1 to 10 carbon atoms.

According to another aspect of the present invention, provided is a method of enhancing the optoelectronic performance of a quantum dots-sensitized solar cell using a co-adsorbent, characterized in that a photoelectrode is dipped into a mixed solution of a co-adsorbent and a quantum dots sensitizer to increase the coverage of the quantum dots sensitizer on the photoelectrode and thereby improve the photoelectric conversion efficiency of the quantum dots-sensitized solar cell, wherein the co-adsorbent has a structure of HS—R—COOH or HS—R—OH where R represents a substituted or unsubstituted organic carbon chain having 1 to 10 carbon atoms.

The substrate of a solar cell should be excellent in light transparency. Generally, there are two types of transparent electrically conductive glass that are for use as the substrate of a solar cell. One is fluorine-doped tin oxide (FTO) transparent electrically conductive glass in which tin oxide (SnO₂) is duped with fluorine (CnO₂₁F), and the other is indium tin oxide (ITO) transparent electrically conductive glass in which indium oxide (In₂O₃) is doped with SnO₂. In the present invention, the first substrate and the second substrate each can be either of the aforementioned types of transparent electrically conductive glass, and preferably FTO.

The photoelectrode is mainly composed of an oxide semiconductor such as TiO₂, SnO₂, ZnO, SrTiO₃. Using different oxide semiconductors as the carrier for adsorbing the sensitizer results in different open-circuit voltages (V_{oc}). TiO₂ is preferable because of its low cost, ease to obtain, good stability, and good effect. However, the present invention is not limited to using TiO₂, and the aforementioned oxide semiconductor such as SnO₂, ZnO, and SrTiO₃ can also be used.

In order to absorb the solar light energy to excite electrons more efficiently, the oxide semiconductor may adsorb sensitizers of smaller energy gap to broaden the light absorption range and facilitate the excitation of electrons. There are two kinds of sensitizers including organic metal dye sensitizers, of which the most typical one is polypyridyl complexes of ruthenium, and quantum dots sensitizers. The present invention uses quantum dots sensitizers, which can be a semiconductor material selected from the group consisting of CdS, CdSe, CdTe, PbS, PbSe, Ag₂S, Ag₂Se, AgSₓSe₁₋ₓ, CuS, Sb₂S₃, Sb₂Se₃, CdSₓSe₁₋ₓ, CdSeₓTe₁₋ₓ, InP, PbSₓSe₁₋ₓ, PbSeₓTe₁₋ₓ, AgInSₓSe₁₋ₓ, AgInS₂, AgInSe₂, AgInTe₂, CuInSₓSe₁₋ₓ, CuInSₓTe₁₋ₓ, CuInS₂, CuInSe₂, CuInTe₂, and CuIn₂S₃, and preferably CuInS_{2.}

I⁻/I₃⁻ electrolytes are used in most of conventional DSSCs so as to reduce the dye from an oxidation state and transfer charges from the back electrode to the dye through a reduction-oxidation reaction. In the QDSSC of the present invention, a polysulfide (S²⁻/Sn²⁻) electrolyte is used. The reduction-oxidation reaction of polysulfide can not only facilitate transferring the holes on the sulfide semiconductor that has absorbed light and been excited, but also allow a higher photocurrent. However, the polysulfide electrolyte will also cause the problem that polysulfide poisons the Pt back electrode, which is usually used in the DSSCs. Therefore, the differences between the QDSSCs according to the present invention and the conventional DSSCs are not only the sensitizer but also the choice of materials of the electrolyte and the back electrode, which are changed in accordance with the sensitizer.

As to the back electrode, materials such as graphono, carbon nanotube, metal sulfides (such as, for example, PbS, NiS, FeS₂, CoS, CuS, Cu₂₋ₓS and Cu₂S), and metal selenides (such as, for example, PbSe, NiSe, FeSe₂, CoSe, CuSe, Cu₂₋ₓSe and Cu₂Se) have better charge transfer capability, and namely are good for reduction-oxidation reaction, with respect to the polysulfide solution. In the present invention, a metal sulfide preferably selected from the group consisting of PbS, NiS, CoS, CuS and Cu₂S is used as the back electrode of the QDSSC together with the polysulfide electrolyte, thereby significantly improving the photoelectric conversion efficiency of the QDSSC.

There are two methods to sensitize the electrode with the quantum dots, including (i) in situ method, by which the quantum dots are prepared on the surface of the photoelectrode film, and (ii) ex situ method, also called pre-synthesized method, by which colloidal quantum dots (CQDs) are made to adhere to the surface of the electrode. The in situ method further includes chemical bath deposition (CBD), successive ionic layer adsorption and reaction (SILAR), and electrodeposition (ED).

In addition, leakage current will be generated in the contact interfaces between liquid electrolyte, wide bandgap semiconductor, and quantum dots to lower the conversion efficiency, and therefore a passivation layer having a bandgap wider than that of the quantum dots should be deposited on the quantum dots adsorbed to the wide bandgap semiconductor in order to avoid causing severe leakage current.

To make the quantum dots adhere to the photoelectrode, the present invention is not limited to using the aforementioned methods, and any method for adsorbing the quantum dots sensitizer to the photoelectrode can be used. Any combination of the aforementioned methods can also be used to adsorb the quantum dots sensitizer and the passivation layer, respectively.

The co-adsorbent as used in the present invention has a structure of HS—R—COOH or HS—R—OH where R represents a substituted or unsubstituted organic carbon chain having 1 to 10 carbon atoms. Specifically, the co-adsorbent having the structure of HS—R—COOH includes, but is not limited to, thioglycolic acid (TGA), L-Cystine, D-Cystine, DL-Cystine, L-cysteine (Cys), D-cysteine, DL-cysteine, L-homocysteine, N-isobutyryl-L-cysteine, N-carbamoyl-L-cysteine, glutathione (GSH), 2-mercaptopropionic acid (2-MPA) 3-mercaptopropionic acid (3-MPA), 4-mercaptobutyric acid, 6-mercaptohexanoic acid, 8-mercaptooctanoic acid, mercaptosuccinic acid, meso-2,3-dimercaptosuccinic acid, 2-methyl-3-sulfanylpropanoic acid, dihydrolipoic acid, thiolactic acid, methyl thioglycolate, ethyl thioglycolate, methyl 3-mercaptopropionate, and pentaerythritol tetrakis(2-mercaptoacetate); the co-adsorbent having the structure of HS—R—OH includes, but is not limited to, 1,4-dithiothreitol (DTT), L-(-)-dithiothreitol, trans-4,5-dihydroxy-1,2-dithiane, 1-mercapto-2-propanol, 2-mercaptoethanol (ME), 4-mercapto-1-butanol, 3-mercapto-1-propanol, 6-mercapto-1-hexanol, and 8-mercapto-1-octanol. Those co-adsorbents having the structure of HS—R—COOH or HS—R—OH can stabilize the bifunctional molecules on the surfaces of the quantum dots so as not to form disulfide bonds, thereby increasing the coverage of the quantum dots on the photoelectrode. The chemical structures of some bifunctional molecules are shown below:

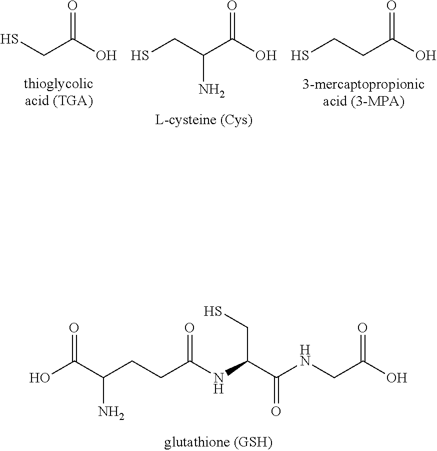

According to the present invention, a required amount of aqueous quantum dots is synthetized by means of a microwave-assisted method, and after the steps such as purification and drying, the required quantum dots sensitizer is prepared. Subsequently, a photoelectrode is dipped into a solution composed of the sensitizer and a co-adsorbent for a period of time, and a layer of passivation layer is deposited, thereby obtaining a photoelectrode with the quantum dots sensitizer adsorbed. The photoelectrode with the quantum dots sensitizer adsorbed is then combined with a back electrode so that the quantum dots-sensitized solar cell according to the present invention is obtained.

The present invention will be further described by referring to the preferred embodiments below, which are, however, not intended to restrict the scope of the present invention.

### BRIEF DESCRIPTION OF THE DRAWINGS

FIG. 1(a) is a TEM (Transmission Electron Microscope) diagram of the aqueous CuInS₂ quantum dots, FIG. 1(b) is an XRD (X-ray Diffraction) diagram of the aqueous CuInS₂ quantum dots, and FIG. 1(c) is an EDS (Energy Dispersive Spectrometer) diagram of the aqueous CuInS₂ quantum dots.

FIG. 2 is schematic diagram showing assembly of the components of a solar cell.

### DESCRIPTION OF PREFERRED EMBODIMENTS

(Synthesis of the aqueous CuInS₂ quantum dots)

A solution was prepared by adding 0.213 ml of CuCl₂ solution, 0.553 ml of InCl₃ solution, and 0.25 ml of sodium citrate (SC) solution (all prepared in advance) into a microwave reaction vial G30, being stirred until its color turned blue, adding 1000 ml of L-cysteine (Cys) precursor solution so that the color became transparent from blue, adding 17.48 ml of deionized water, and fast adding Na2S with stirring so that the color became yellow from transparent, wherein Cu:In:SC:Cys:S is 1:4:16:7.2:6.5.

The resultant solution was placed in a microwave assisting device Microwave 300 at a standard mode, and a microwave reaction was carried out at 180° C. for 15 minutes. The cooling temperature was set to 55° C., and the pressure during the reaction was about 10.5-11 Bar. The color of the solution turned deep brown from yellow. After reaction, the solution was mixed with 2-propanol, and then centrifuged to collect a precipitate. The precipitate was placed in an oven at 40° C. for 16-18 hours, and the dried substance in deep brown color was the aqueous CuInS₂ quantum dots as synthetized.

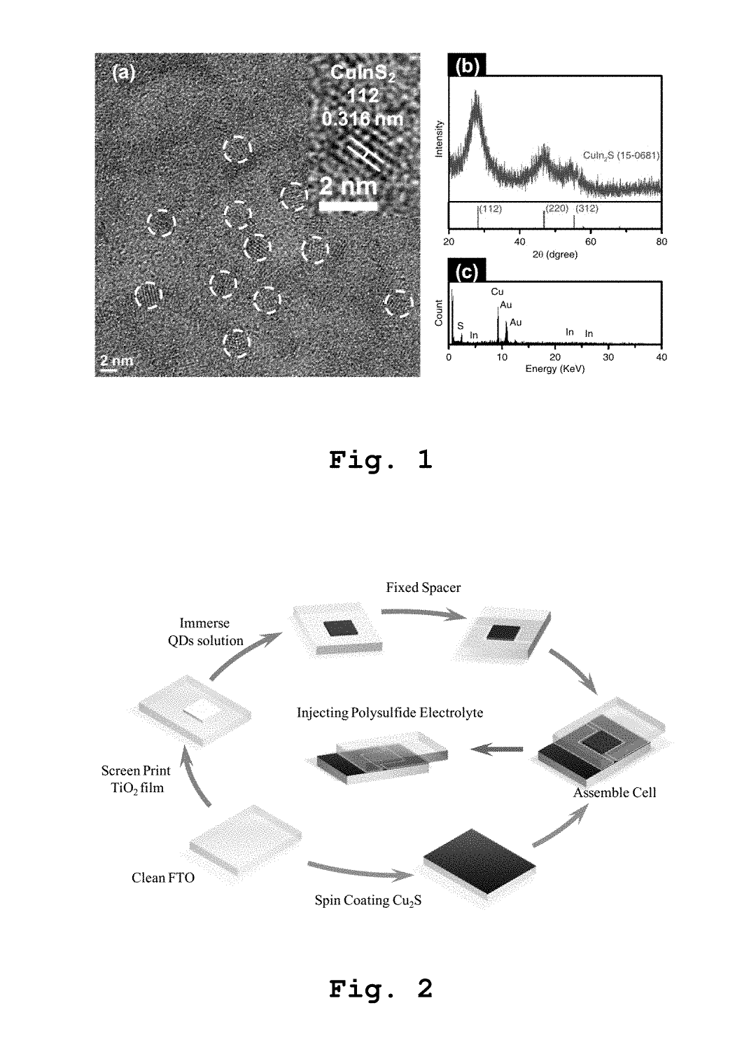

FIG. 1(a) shows the lattice structure of the aqueous CuInS₂ quantum dots, obtained from an image analysis conducted with a high resolution transmission electron microscope. FIG. 1(b) shows the XRD signal of the aqueous CuInS₂ quantum dots. In comparison with CuInS₂ with tetragonal structure (JCPDS-15-0681), the XRD signal of the aqueous CuInS₂ quantum dots quite correspond to that of CuInS₂ with tetragonal structure which shows three main peaks (112), (220), and (312) at 2θ=28.2°, 46.8°, and 55.3°, respectively, and it was thus confirmed that the synthetized material was CuInS₂ quantum dots. FIG. 1(C) is an EDS diagram of the aqueous CuInS₂ quantum dots, which shows that there are element signals of Cu, In, S, and Au. Because the EDS element analysis was conducted by dropping the aqueous CuInS₂ quantum dots on a gold specimen after dissolving, an Au signal appeared in the EDS result.

(Adsorption of the aqueous CuInS₂ quantum dots)

The dried aqueous CuIn3₂ quantum dots were dissolved in water, and then different kinds of co-absorbents were added in different concentrations so as to prepare aqueous CuInS₂ quantum dots solutions containing the kinds and concentrations of co-absorbents listed in the Examples below. Subsequently, a photoelectrode in which a TiO₂ film was formed on an FTO electrically conductive glass was immersed in each of the aforementioned aqueous CuInS₂ quantum dots solutions at 40° C. for 24 hours, and then the photoelectrode was taken out, washed with methanol, and dried. Subsequently, a ZnS passivation layer was deposited thereon with the SILAR method. Finally, a TiO₂ photoelectrode having CuInS₂ quantum dots adsorbed was thus obtained.

The obtained TiO₂ photoelectrode having CuInS₂ quantum dots adsorbed was combined with the Cu₂S back electrode, which was prepared with a spin coating method, and the polysulfide electrolyte, which was prepared in advance by the following steps of weighting 4.3232 g of Na₂S, 0.1491 g of KCl, and 0.6401 g of S powder, dissolving these solid solutes in 7 ml of water, followed by adding 3 ml of methanol, and then adding 29.5 mg of GuSCN into 5 ml of the aforementioned mixed solution. The assembly of the solar cell is shown in FIG. 2.

Table 1 is the analysis result of the optoelectronic performance of the QDSSCs produced by using different concentrations of DTT as the co-adsorbent, in which J_{sc} represents a short-circuit current density (where the short-circuit current is a current generated upon irradiation) and is defined as a current density measured when the applied voltage is zero, V_{oc} represents an open-circuit voltage and is defined as a voltage applied when the measured current density is zero, FF (fill factor) is defined as an actual largest output power divided by a target output power (J_{sc}×V_{oc}), which is a dimensionless value, and can be used as an index for indicating the difference between the actual solar cell and the ideal solar cell, as a solar cell is closer to an ideal solar cell if the FF value is closer to 1, and η represents the photoelectric conversion efficiency of a solar cell and is defined as a ratio of the largest output power to the power of an incident light.

TABLE 1
Efficiency of QDSSCs with different DTT concentrations

| | | J_{sc} | V_{oc} | FF | η |
|---|---|---|---|---|---|
| | DTT Conc. | (mA/cm²) | (mV) | (%) | (%) |
| Compar. | 0M | 0.282 | 290 | 46.8 | 0.038 |
| Ex. 1 | | | | | |
| Compar. | 0.1M | 0.296 | 240 | 50.3 | 0.036 |
| Ex. 2 | | | | | |
| Ex. 1 | 0.5M | 2.046 | 478 | 54.5 | 0.533 |
| Ex. 2 | 4.0M | 7.207 | 592 | 60.6 | 2.587 |

It can he learned from the Comparative Examples 1 and 2 that the η values were merely 0.038% and 0.036%, respectively, for the aqueous CuInS₂ quantum dots dissolved in pure water and low concentration 0.1 M of DTT. When the DTT concentration was increased to 0.5 M, all data of the device increased greatly, indicating that a high concentration disulfide bond reagent can stabilize the bifunctional molecule on the surfaces of the aqueous CuInS₂ quantum dots so that the carboxylic group of the bifunctional molecule can successfully bond to TiO₂, thereby greatly increasing the coverage and providing more excited electrons to increase J_{sc}. V_{oc} depends on the Fermi energy level of TiO₂ and the potential difference of oxidation-reduction pairs in the electrolyte. The increase in the coverage of the aqueous CuInS₂ quantum dots implies that more electrons are injected into TiO₂ so that the Fermi energy level of TiO₂ moves toward a negative potential, thereby increasing the potential difference with respect to the oxidation-reduction pairs of the electrolyte and increasing V_{oc}. In the Example 2, the DTT concentration was further increased to 4.0 M, and therefore J_{sc} increased greatly to 7.207 mA/cm², V_{oc} increased to 592 mV, FF increased to 60.6%, and η even increased from 0.533% to 2.587%, indicating that the reduction conducted in high concentration may provid the wide bandgap oxide semiconductor with a high load of aqueous CuInS₂ quantum dots.

Table 2 is the analysis result of the optoelectronic performance of the QDSSCs produced by using different bifunctional molecules as the co-adsorbent.

TABLE 2
Efficiency of QDSSCs with 0.5M of
different bifunctional molecules

| | | J_{sc} | V_{oc} | FF | η |
|---|---|---|---|---|---|
| | co-adsorbent | (mA/cm²) | (mV) | (%) | (%) |
| Ex. 1 | DTT | 2.046 | 478 | 54.5 | 0.533 |
| Ex. 3 | TGA | 12.820 | 640 | 54.1 | 4.438 |
| Ex. 4 | Cys | 4.462 | 544 | 56.8 | 1.379 |
| Ex. 5 | GSH | 6.930 | 628 | 56.4 | 2.455 |

It can be learned from Table 2 that the photoelectric conversion efficiencies of the solar cells of the Examples 3 to 5, in which TGA, Cys, and GSH, respectively, were used as the co-adsorbent, all increased greatly, in comparison with the Example 1, in which DTT was used as the co-adsorbent. TGA, Cys, and GSH each have carboxylic groups in their molecular structures, which may be a main reason why the coverage increased greatly. Among them, TGA as the co-adsorbent has the best result for photoelectric conversion efficiency, followed by GSH, and the last is Cys, and this may be because TGA's molecular structure and thus steric effect are smaller so that the aqueous CuInS₂ quantum dots could be successfully adsorbed to the surface of TiO₂ and the photoelectric conversion efficiency greatly increased to 4.438%. GSH has two carboxylic groups in its molecular structure, which can provide a higher capability of bonding to TiO₂. However, the said molecular structure and thus the steric effect are larger, so that its photoelectric conversion efficiency of 2.455% was worse than that of TGA. The steric effect of the molecular structure of Cys is between those of TGA and GSH, but its photoelectric conversion efficiency is worse than those of TGA and GSH. It is inferred that Cys is not higher in capability of reducing disulfide bonds than GSH, and therefore Cys is worse in efficiency than GSH even if its steric effect is smaller.

Table 3 is the analysis result of the optoelectronic performance of the QDSSCs produced by using different concentrations of TGA as the co-adsorbent.

TABLE 3
Efficiency of QDSSCs with different TGA concentrations

| | | J_{sc} | V_{oc} | FF | η |
|---|---|---|---|---|---|
| | TGA Conc. | (mA/cm²) | (mV) | (%) | (%) |
| Ex. 6 | 0.1M | 9.230 | 616 | 56.7 | 3.225 |
| Ex. 3 | 0.5M | 12.820 | 640 | 54.1 | 4.438 |
| Ex. 7 | 1.0M | 14.015 | 642 | 51.8 | 4.661 |
| Ex. 8 | 2.0M | 14.415 | 642 | 52.1 | 4.821 |
| Ex. 9 | 4.0M | 14.837 | 630 | 52.6 | 4.920 |
| Ex. 10 | 6.0M | 13.705 | 650 | 50.9 | 4.534 |

According to the result of Table 2, TGA was the best co-absorbent for photoelectric conversion efficiency and thus was used in concentrations of 0.1 M to 6.0 M in the Examples 6 to 10, respectively. It can be learned from Table 3 that the photoelectric conversion efficiency increased as the TGA concentration was increased from 0.1 M to 4.0 M. The best result was the Example 9 with 4.0 M TGA used and the photoelectric conversion efficiency was 4.920%.

Table 4 is the analysis result of the optoelectronic performance of the QDSSCs produced by using 4.0 M TGA as the co-adsorbent and immersing the photoelectrode for different periods of time.

TABLE 4
Efficiency of QDSSCs with immersion in
0.4M TGA for different periods of time.

| | Immersion | | J_{sc} | V_{oc} | FF | η |
|---|---|---|---|---|---|---|
| | Time | | (mA/cm²) | (mV) | (%) | (%) |
| Ex. 11 | 0.5 | hr | 7.634 | 626 | 61.2 | 2.926 |
| Ex. 12 | 1 | hr | 9.225 | 630 | 57.7 | 3.352 |
| Ex. 13 | 3 | hr | 12.133 | 630 | 57.0 | 4.360 |
| Ex. 14 | 6 | hr | 12.998 | 630 | 54.5 | 4.461 |
| Ex. 15 | 12 | hr | 13.691 | 624 | 54.0 | 4.615 |
| Ex. 9 | 24 | hr | 14.837 | 630 | 52.6 | 4.920 |

According to the result of Table 3, 0.4 M TGA exhibited the best result for photoelectric conversion efficiency among different concentrations of TGA, and thus was used as the co-adsorbent in the Examples 11 to 15 to determine the influence of immersion time on the photoelectric conversion efficiency of the solar cell. It can be learned from Table 4 that J_{sc} increased from 7.634 mA/cm² to 12.133 mA/cm² and the photoelectric conversion efficiency increased from 2.926% to 4.360% when the immersion time was increased from 0.5 hours to 3 hours, while J_{sc} increased from 12.133 mA/cm² to 14.837 mA/cm² and the photoelectric conversion efficiency increased merely from 4.360% to 4.920% when the immersion time was increased from 3 hours to 24 hours. In other words, taking the immersion time of 3 hours as a cut-off point, the photoelectric conversion efficiency rose rapidly before 3 hours and tended to rise gently after 3 hours. Also, it can be learned from the results of all immersion time conditions that as the immersion time was increased, FF decreased from 61.2% at 0.5 hours to 52.6% at 24 hours, indicating that the coverage of the quantum dots increases as the immersion time increases, but too many quantum dots will cause a continuous increase in internal impedance and thus a reduction in FF, thereby slowing down the rising of the photoelectric conversion efficiency.

The TiO₂ photoelectrode has to be immersed in a solution composed of both TGA co-adsorbent and aqueous CuInS₂ quantum dots so as to have a better photoelectric conversion efficiency. In the Comparative Examples 3 to 5, the optoelectronic performance of the QDSSCs produced from aqueous CuInS₂ quantum dots with the TGA co-adsorbent added in different sequences was analyzed.

In Table 5, the Comparative Example 3 was to immerse the TiO₂ photoelectrode in the TGA co-adsorbent for 24 hours and then in the aqueous CuInS₂ quantum dots for 24 hours; the Comparative Example 4 was to immerse the TiO₂ photoelectrode in the aqueous CuInS₂ quantum dots for 24 hours and then in the TGA co-adsorbent for 24 hours; the Comparative Example 5 was to immerse the TiO₂ photoelectrode only in the TGA co-adsorbent for 24 hours without being immersed in any aqueous quantum dots.

TABLE 5
Efficiency of QDSSCs with different immersion sequences

| | J_{sc} | V_{oc} | FF | η |
|---|---|---|---|---|
| | (mA/cm²) | (mV) | (%) | (%) |
| Compar. | 0.597 | 354 | 53.8 | 0.114 |
| Ex. 3 | | | | |
| Compar. | 1.411 | 460 | 55.2 | 0.358 |
| Ex. 4 | | | | |
| Compar. | 0.495 | 410 | 38.1 | 0.077 |
| Ex. 5 | | | | |
| Ex. 3 | 12.820 | 640 | 54.1 | 4.438 |

It can be learned from Table 5 that the photoelectric conversion efficiencies of the Comparative Examples 3 and 4 were far lower than that of the Example 3. On the other hand, the photoelectric conversion efficiency of the Comparative Example 5, in which the TiO₂ photoelectrode was immersed only in the TGA co-adsorbent for 24 hours without being immersed in any aqueous quantum dots, is even merely 0.077%. It is thus demonstrated that a mixed solution composed of both TGA co-adsorbent and aqueous CuInS₂ quantum dots results in a better photoelectric conversion efficiency.

Table 6 is the analysis result of the optoelectronic performance of the QDSSCs produced by using aqueous CdSe, CdSeₓTe₁₋ₓ, AgInSe₂, and AgInS₂ quantum dots.

TABLE 6
Efficiency of aqueous CdSe, CdSeₓTe₁₋ₓ, AqInSe₂, and AqInS₂
QDSSCs with the TGA co-adsorbent

| | | co- | J_{sc} | V_{oc} | FF | |
|---|---|---|---|---|---|---|
| | QD | adsorbent | (mA/cm²) | (mV) | (%) | η (%) |
| Compar. | CuInS₂ | — | 0.282 | 282 | 46.8 | 0.038 |
| Ex. 6 | | | | | | |
| Ex. 16 | CuInS₂ | 4M TGA | 14.478 | 630 | 53.1 | 4.864 |
| Compar. | AgInS₂ | — | 0.178 | 212 | 47.5 | 0.018 |
| Ex. 7 | | | | | | |
| Ex. 17 | AqInS₂ | 4M TGA | 6.518 | 382 | 64.0 | 1.594 |
| Compar. | CdSe | — | 0.385 | 264 | 45.7 | 0.046 |
| Ex. 8 | | | | | | |
| Ex. 18 | CdSe | 4M TGA | 4.759 | 552 | 53.8 | 1.413 |
| Compar. | CdSeₓTe₁₋ₓ | — | 0.640 | 384 | 46.0 | 0.113 |
| Ex. 9 | | | | | | |
| Ex. 19 | CdSeₓTe₁₋ₓ | 4M TGA | 14.38 | 630 | 50.5 | 4.578 |
| Compar. | AgInSe₂ | — | 1.538 | 492 | 50.4 | 0.381 |
| Ex. 10 | | | | | | |
| Ex. 20 | AgInSe₂ | 4M TGA | 16.39 | 610 | 54.1 | 5.411 |

It can be learned from Table 6 that the photoelectric conversion efficiencies of the solar cells using the aqueous CdSeₓTe₁₋ₓ and AgInSe₂ quantum dots and the TGA co-adsorbent also increased notably. Also, the photoelectric conversion efficiencies of the AgInS₂ and CdSe QDSSCs increased from 0.018% and 0.046% to 1.594% and 1.413%, respectively. Although their improvements are not as obvious as that of CuInS₂, yet it can still be demonstrated that the TGA co-adsorbent can be used with various aqueous quantum dots to improve the coverage.

Table 7 further provides the analysis result of the optoelectronic performance of the QDSSCs produced by immersing the TiO₂ photoelectrode in different concentrations of GSH, 3-MPA, and Cys co-adsorbents for 24 hours, which shows that different kinds of co-adsorbents all can improve the efficiencies of the QDSSCs by increasing their concentrations.

TABLE 7
Efficiency of the QDSSCs with different
concentrations of GSH, 3-MPA, and Cys

| | | | J_{sc} | V_{oc} | FF | η |
|---|---|---|---|---|---|---|
| | co-adsorbent | | (mA/cm²) | (mV) | (%) | (%) |
| Compar. | 0.1M | GSH | 0.108 | 490 | 41.2 | 0.136 |
| Ex. 11 | | | | | | |
| Ex. 5 | 0.5M | GSH | 6.930 | 628 | 56.4 | 2.455 |
| Ex. 21 | 1.0M | GSH | 12.234 | 676 | 51.7 | 4.273 |
| Ex. 22 | 2.0M | GSH | 11.862 | 660 | 53.5 | 4.185 |
| Compar. | 0.1M | 3-MPA | 0.878 | 496 | 58.8 | 0.256 |
| Ex. 12 | | | | | | |
| Ex. 23 | 0.5M | 3-MPA | 2.620 | 574 | 56.0 | 0.842 |
| Ex. 24 | 1.0M | 3-MPA | 5.648 | 600 | 58.2 | 1.973 |
| Ex. 25 | 2.0M | 3-MPA | 10.596 | 624 | 53.5 | 3.536 |
| Ex. 26 | 4.0M | 3-MPA | 11.693 | 632 | 51.2 | 3.787 |
| Compar. | 0.1M | Cys | 0.707 | 412 | 48.0 | 0.140 |
| Ex. 13 | | | | | | |
| Ex. 4 | 0.5M | Cys | 4.462 | 544 | 56.8 | 1.379 |
| Ex. 27 | 1.0M | Cys | 8.174 | 616 | 57.4 | 2.888 |
| Ex. 28 | 2.0M | Cys | 9.403 | 618 | 53.1 | 3.084 |
| Ex. 29 | 4.0M | Cys | 9.539 | 626 | 52.8 | 3.154 |

1. A quantum dots-sensitized solar cell, comprising:
a photoelectrode, formed on a first substrate and having a quantum dots sensitizer adsorbed thereon;
a back electrode, formed on a second substrate; and
a polysulfide electrolyte, injected between the photoelectrode and the back electrode;
wherein the photoelectrode having the quantum dots sensitizer adsorbed is modified by a co-adsorbent, and the co-adsorbent has a structure of HS—R—COOH or HS—R—OH where R represents a substituted or unsubstituted organic carbon chain having 1 to 10 carbon atoms.

2. The quantum dots-sensitized solar cell according to claim 1, wherein the co-adsorbent having the structure of HS—R—COOH is selected from the group consisting of thioglycolic acid (TGA), L-Cystine, D-Cystine, DL-Cystine, L-cysteine (Cys), D-cysteine, DL-cysteine, L-homocysteine, N-isobutyryl-L-cysteine, N-carbamoyl-L-cysteine, glutathione (GSH), 2-mercaptopropionic acid (2-MPA)-3-mercaptopropionic acid (3-MPA), 4-mercaptobutyric acid, 6-mercaptohexanoic acid, 8-mercaptooctanoic acid, mercaptosuccinic acid, meso-2,3-dimercaptosuccinic acid, 2-methyl-3-sulfanylpropanoic acid, dihydrolipoic acid, thiolactic acid, methyl thioglycolate, ethyl thioglycolate, methyl 3-mercaptopropionate, and pentaerythritol tetrakis(2-mercaptoacetate).

3. The quantum dots-sensitized solar cell according to claim 1, wherein the co-adsorbent having the structure of HS—R—OH is selected from the group consisting of 1,4-dithiothreitol (DTT), L-(−)-dithiothreitol, trans-4,5-dihydroxy-1,2-dithiane, 1-mercapto-2-propanol, 2-mercaptoethanol (ME), 4-mercapto- 1-butanol, 3-mercapto-1-propanol, 6-mercapto-1-hexanol, and 8-mercapto-l-octanol

4. The quantum dots-sensitized solar cell according to claim 1, wherein the first substrate and the second substrate each are either of FTO transparent electrically conductive glass and ITO transparent electrically conductive glass.

5. The quantum dots-sensitized solar cell according to claim 1, wherein there is a layer of an oxide semiconductor selected from the group consisting of TiO₂, SnO₂, ZnO and SrTiO₃ on the photoelectrode.

6. The quantum dots-sensitized solar cell according to claim 1, wherein the quantum dots sensitizer is a semiconductor material selected from the group consisting of CdS, CdSe, CdTe, PbS, PbSe, Ag₂S, Ag₂Se, AgSₓSe₁₋ₓ, CuS, Sb₂S₃, Sb₂Se₃, CdSₓSe₁₋ₓ, CdSeₓTe₁₋ₓ, InP, PbSₓSe₁₋ₓ, PbSeₓTe₁₋ₓ, AgInSₓSe₁₋ₓ, AgInS₂, AgInSe₂, AgInTe₂, CuInSₓSe₁₋ₓ, CuInSₓTe₁₋ₓ, CuInS₂, CuInSe₂, CuInTe₂, and CuIn₂S₃.

7. The quantum dots-sensitized solar cell according to claim 1, wherein a material of the back electrode is a metal sulfide selected from the group consisting of PbS, NiS, CoS, CuS, and Cu₂S.

8. A method of enhancing the optoelectronic performance of a quantum dots-sensitized solar cell using a co-adsorbent, characterized in that a photoelectrode is dipped into a mixed solution of a co-adsorbent and a quantum dots sensitizer to increase the coverage of the quantum dots sensitizer on the photoelectrode and thereby improve the photoelectric conversion efficiency of the quantum dots-sensitized solar cell, wherein the co-adsorbent has a structure of HS—R—COOH or HS—R—OH where R represents a substituted or unsubstituted organic carbon chain having 1 to 10 carbon atoms.

9. The method according to claim 8, wherein the co-adsorbent having the structure of HS—R—COOH is selected from the group consisting of thioglycolic acid (TGA), L-Cystine, D-Cystine, DL-Cystine, L-cysteine (Cys), D-cysteine, DL-cysteine, L-homocysteine, N-isobutyryl-L-cysteine, N-carbamoyl-L-cysteine, glutathione (GSH), 2-mercaptopropionic acid (2-MPA) 3-mercaptopropionic acid (3-MPA), 4-mercaptobutyric acid, 6-mercaptohexanoic acid, 8-mercaptooctanoic acid, mercaptosuccinic acid, meso-2,3-dimercaptosuccinic acid, 2-methyl-3-sulfanylpropanoic acid, dihydrolipoic acid, thiolactic acid, methyl thioglycolate, ethyl thioglycolate, methyl 3-mercaptopropionate, and pentaerythritol tetrakis(2-mercaptoacetate).

10. The method according to claim 8, wherein the co-adsorbent having the structure of HS—R—OH is selected from the group consisting of 1,4-dithiothreitol (DTT) , L-(−)-dithiothreitol, trans-4,5-dihydroxy-1,2-dithiane, 1-mercapto-2-propanol, 2-mercaptoethanol (ME), 4-mercapto-1-butanol, 3-mercapto-1-propanol, 6-mercapto-1-hexanol, and 8-mercapto-1-octanol.

11. The method according to claim 8, wherein the quantum dots sensitizer is a semiconductor material selected from the group consisting of CdS, CdSe, CdTe, PbS, PbSe, Ag₂S, Ag₂Se, AgSₓSe₁₋ₓ, CuS, Sb₂S₃, Sb₂Se₃, CdSₓSe₁₋ₓ, CdSeₓTe₁₋ₓ, InP, PbSₓSe₁₋ₓ, PbSeₓTe₁₋ₓ, AgInSₓSe₁₋ₓ, AgInS₂, AgInSe₂, AgInTe₂, CuInSₓSe₁₋ₓ, CuInSₓTe₁₋ₓ, CuInS₂, CuInSe2, CuInTe₂, and CUIn₂S₃.
